(19) United States
(12) Patent Application Publication
(10) Pub. No.: US 2013/0220551 A1
(43) Pub. Date: Aug. 29, 2013

(54) SUBSTRATE PROCESSING APPARATUS

(71) Applicant: CANON ANELVA CORPORATION, (US)

(72) Inventor: Reiji Saito, Sagamihara-shi (JP)

(73) Assignee: CANON ANELVA CORPORATION, Kawasaki-shi (JP)

(21) Appl. No.: 13/854,563

(22) Filed: Apr. 1, 2013

Related U.S. Application Data
(63) Continuation of application No. PCT/JP2011/005254, filed on Sep. 16, 2011.

(30) Foreign Application Priority Data
Oct. 7, 2010 (JP) 2010-227465

(51) Int. Cl. B05C 13/02; C23C 14/50; C23C 16/458

(52) U.S. Cl. CPC B05C 13/02; C23C 16/458; C23C 14/505
USPC 156/345.55; 118/730; 204/298.15

(57) ABSTRACT

A substrate processing apparatus includes a substrate stage, a strut which supports the substrate stage, a first rotation drive portion which rotates the support, and at least three lift pins which are provided in the substrate stage. The substrate processing apparatus includes an elevation mechanism for vertically moving the lift pins. The elevation mechanism includes a first rotating member which is disposed around the support and rotates about the support, a second rotation drive portion which rotates about a rotation axis at a position offset from the rotation axis and rotates the first rotating member, at least three second rotating members which rotate while engaging with rotation of the first rotating member and are disposed below the lift pins, mobile bodies which linearly move upon rotation of the second rotating members, and pins which vertically move the lift pins.

### TECHNICAL FIELD

The present invention relates to a substrate processing apparatus for applying predetermined processing to a substrate.

### BACKGROUND ART

In general, an electronic device is manufactured by performing various types of processing, for example, deposition, etching, oxidation, and diffusion, for a substrate. With the microfabrication and higher integration of electronic devices, there is already known a so-called clustered processing system in which a plurality of substrate processing apparatuses configured to perform the same processing are coupled to each other through a common transport chamber to increase throughput and yield.

The processing system is provided with a plurality of transport robots capable of, for example, bending, stretching, swiveling, and horizontally moving. When transporting a substrate into the clustered processing system, for example, it is possible to transport the substrate from a cassette to the substrate processing apparatus side or from the substrate processing apparatus side to the cassette by transporting the substrate between the transport arms of a plurality of transport robots.

PTL 1 discloses an arrangement configured to mount a substrate on a substrate stage by using a transport robot and lift pins capable of performing elevating operation. According to the arrangement disclosed in PTL 1, the transport robot mounts a substrate on the substrate stage in two steps instead of directly mounting the substrate on the substrate stage. First of all, the lift pins provided in the substrate stage move upward to a position higher than the substrate mounting surface of the substrate stage, and the transport robot transports the substrate onto the lift pins. The lift pins then move downward to transport the substrate onto the substrate mounting surface of the substrate stage. The two transport steps allow to stably mount the substrate onto the substrate mounting surface of the substrate stage.

### CITATION LIST

### Patent Literature

PTL 1: Japanese Patent Laid-Open No. 7-7072

### SUMMARY OF INVENTION

### Technical Problem

Recently, however, a power introducing mechanism for introducing power to an electrostatic attraction electrode, a rotating mechanism for rotating the substrate stage, and the like are provided below the substrate stage. This further complicates the arrangement of the substrate holder. This makes it difficult to provide an elevation mechanism for moving the lift pin up and down below the substrate holder.

If the apparatus sizes are standardized, there are various restrictions. For example, in an ion beam etching apparatus, an ion source is disposed so as to set its emitting surface perpendicular to the ground in order to minimize the attachment of particles emitted from the ion source to a substrate. To dispose a substrate at a position to face the ion source, the substrate transported from the transport chamber onto the substrate holder in the ion beam etching apparatus is attracted to the electrostatic attraction stage, and the substrate holder is rotated toward the ion source. The apparatus then performs an etching process. In this series of operations, the substrate holder must not interfere with the vacuum chamber of the ion beam etching apparatus. According to the SEMI/MESC standards, restrictions on the reach of the stretchable arm of a transport robot define the distance from a connecting surface with the transport chamber of this substrate processing apparatus to the center of the substrate holder. It is therefore necessary to achieve a reduction in the size of the substrate holder.

Under these restrictions, as a result of earnest studies, the present inventors have found a technique of synchronously moving a substrate up and down while miniaturizing the substrate holder.

The present invention has been made in consideration of the above problems in the prior art, and has as its object to provide a substrate processing apparatus which can synchronously move a substrate up and down while achieving a reduction in the thickness of the apparatus.

### Solution to Problem

In order to achieve the above object, there is provided a substrate processing apparatus of the present invention including a substrate stage, a support which supports the substrate stage, a first rotation drive portion which rotates the support, and at least three lift pins which are provided in the substrate stage and configured to vertically move in a vertical direction relative to a surface of the substrate stage on which a substrate is mounted, comprising:

an elevation unit configured to vertically move the lift pins,

the elevation unit comprising

a first rotating member which is disposed around the support and rotates about the support coaxially with a rotation axis of the support,

a second rotation drive portion which rotates about a rotation axis at a position offset from the rotation axis and rotates the first rotating member by transmitting the rotation to the first rotating member through a transmission member,

at least three second rotating members which rotate while engaging with rotation of the first rotating member and are disposed below the lift pins,

mobile bodies which linearly move upon rotation of the second rotating members, and

pins which vertically move the lift pins upon linear movements of the mobile bodies.

Another substrate processing apparatus of the present invention is a substrate processing apparatus including a substrate stage, a support which supports the substrate stage, and at least three lift pins which are provided in the substrate stage and configured to vertically move in a vertical direction relative to a surface of the substrate stage on which a substrate is mounted, comprising:

an elevation unit configured to vertically move the lift pins,

the elevation unit comprising

a first rotating member which is disposed around the support and rotates about the support coaxially with a rotation axis of the support,

a second rotation drive portion which rotates about a rotation axis at a position offset from the rotation axis and rotates the first rotating member by transmitting the rotation to the first rotating member through a transmission member,

at least three second rotating members which rotate while engaging with rotation of the first rotating member and are disposed below the lift pins, and

mobile bodies which linearly move upon rotation of the second rotating members,

wherein the lift pins vertically move upon linear movements of the mobile bodies.

### Advantageous Effects of Invention

According to the present invention, it is possible to provide a substrate processing apparatus which can synchronously move a substrate up and down while achieving a reduction in the thickness of the apparatus by moving lift pins up and down through a first rotating member.

Alternatively, it is possible to eliminate variations in the vertical movements of the lift pins and move a substrate up and down even in a case in which the second rotation drive portion disposed at a position offset from the rotation axis of the substrate stage is operated.

Other features and advantages of the present invention will be apparent from the following description taken in conjunction with the accompanying drawings. Note that the same reference numerals denote the same or like components throughout the accompanying drawings.

### BRIEF DESCRIPTION OF DRAWINGS

FIG. 1 is a view showing the overall arrangement of a substrate processing apparatus including a substrate support apparatus according to the present invention;

FIG. 2 is a view for explaining the rotating operation of a substrate holder;

FIG. 3 is a schematic sectional view of the substrate holder shown in FIG. 1;

FIG. 4 is an upper perspective view of a substrate elevation unit;

FIG. 5 is a schematic plan view of a first rotating member;

FIG. 6 is a detailed sectional view of the substrate elevation unit;

FIG. 7 is a schematic sectional view for explaining a state in which the elevation unit has lifted a substrate;

FIG. 8 is a view for explaining the elevating operation of a ball screw;

FIG. 9 is a sectional view of a substrate processing apparatus according to the second embodiment; and

FIG. 10 is a plan view for explaining an electronic device manufacturing apparatus according to the third embodiment.

### DESCRIPTION OF EMBODIMENTS

### First Embodiment

The first embodiment of the present invention will be described below with reference to the accompanying drawings. Needless to say, the members, arrangements, and the like to be described below provide an example of embodying the present invention, and do not limit the present invention. They can be variously modified within the spirit and scope of the invention. In the drawings described below, the same reference numerals denote components having the same functions, and a repetitive description of them will be omitted.

Although this embodiment will exemplify an ion beam etching apparatus (to be referred to as an IBE apparatus hereinafter) as a substrate processing apparatus, the present invention is not limited to this. Substrate processing apparatuses according to the present invention include, for example, other types of etching apparatuses and plasma processing apparatuses such as sputtering deposition apparatuses, PVD apparatuses, and CVD apparatuses. The substrate support apparatus (substrate holder) according to an embodiment of the present invention provides an arrangement for mounting the substrate received from a transport robot onto a substrate stage and supports (fixes) the substrate, and can be applied to the above substrate processing apparatus.

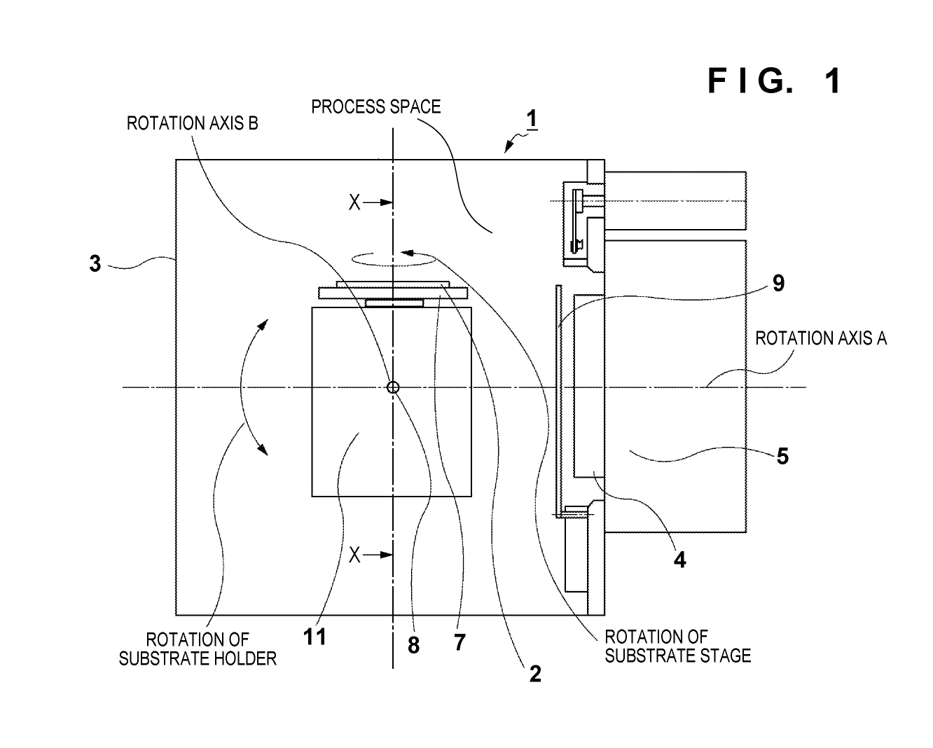

FIG. 1 is a schematic sectional view, viewed from a side surface of the IBE apparatus, for explaining the overall arrangement of an IBE apparatus 1 according to the first embodiment of the present invention.

The IBE apparatus 1 shown in FIG. 1 includes a vacuum vessel 3, a discharge chamber 5, an extraction electrode 4, a substrate holder 11, and a shutter apparatus 9. The discharge chamber 5 generates a plasma by applying high-frequency power to an introduced gas. The extraction electrode 4 generates an electric field for extracting ions from the plasma generated by the discharge chamber 5 into the process space in the vacuum vessel 3. The substrate holder 11 holds a substrate 2. The shutter apparatus 9 shields against the ion beam emitted from the discharge chamber 5 into the process space in which the substrate 2 is mounted. The discharge chamber 5 is coupled to a side surface of the vacuum vessel 3. The substrate holder 11 is disposed to face the discharge chamber 5. A neutralizer (not shown) for neutralizing the charges of the ions emitted from the discharge chamber 5 is provided on a side surface of the process space. Although not shown, a transport chamber is coupled to the vacuum vessel 3 through a gate valve, and a transport robot is provided in the center of the transport chamber.

The substrate 2 transported by the transport robot is placed on lift pins 16 of the substrate holder 11. Thereafter, the lift pins 16 move down to mount the substrate 2 on a substrate stage 7. The substrate 2 is then fixed on the substrate stage 7 by a fixing unit such as an electrostatic chuck or mechanical chuck. The lift pins 16 are provided in the substrate stage 7. The lift pins 16 can move up and down in the vertical direction relative to the surface of the substrate stage on which a substrate can be mounted. The lift pins 16 include at least three lift pins to support the substrate 2. This embodiment will exemplify an arrangement including three lift pins. However, the spirit and scope of the present invention are not limited to this example, and the present invention can be applied to an arrangement including three or more lift pins.

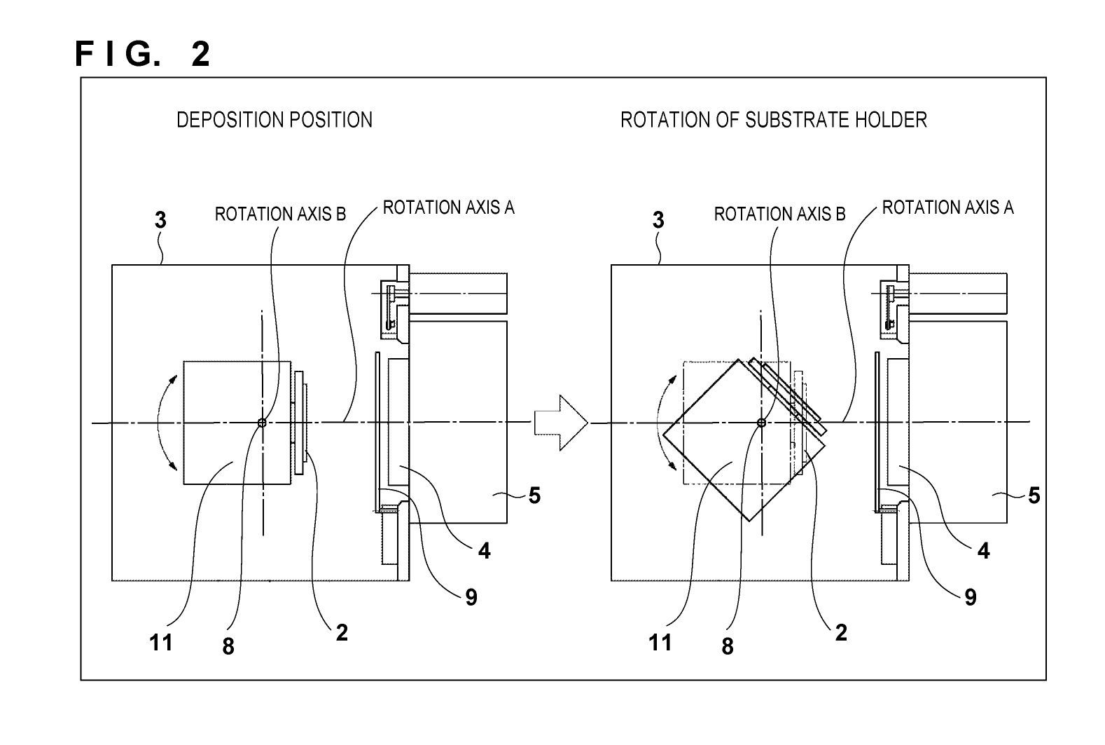

FIG. 2 is a view for explaining the rotating operation of the substrate holder 11. A rotating support portion 8 can rotate about a rotation axis A relative to the vacuum vessel 3. With this rotation (about 60 rotations per min), the substrate stage 7 supported on the rotating support portion 8 also rotates. In addition, the rotating support portion 8 can change the surface of the substrate held on the substrate stage 7, centered on a rotation axis B, relative to an ion beam. That is, the rotating operation of the rotating support portion 8 can change the angle of a substrate deposition surface relative to the incident direction of ions from the discharge chamber 5. Changing the incident angle of ions to the substrate deposition surface can make the ions obliquely strike the deposition surface of the substrate 2. This makes it possible to perform accurate etching. In this case, as described above, since the fixing unit fixes the substrate 2 on the substrate stage 7, the rotating support portion 8 can rotate together with the substrate stage 7 relative to an ion beam.

The IBE apparatus 1 irradiates the substrate 2 mounted on the substrate holder 11 with ions from the discharge chamber 5 to etch a laminated film on the substrate 2. The rotating support portion 8 supports the substrate holder 11. The electrostatic chuck mechanism provided in the substrate holder 11 chucks and holds the substrate 2 on the substrate stage 7.

The shutter apparatus 9 is provided between the discharge chamber 5 and the substrate holder 11. The opening/closing operation of the shutter apparatus 9 can shield against the ions emitted from the discharge chamber 5 onto the substrate 2 on the substrate stage 7 on the substrate holder 11.

First of all, the discharge chamber 5 generates a plasma by applying power to an inert gas (for example, argon gas) introduced by a gas introduction unit (not shown). The extraction electrode 4 extracts ions from the plasma generated in the discharge chamber 5 and emits the ions toward the substrate 2. After the substrate 2 is irradiated with an ion beam for a predetermined period of time, the shutter apparatus 9 actuates to shield against the ion beam, thus completing the etching process. Note that the inert gas to be used for the generation of plasma is not limited to argon gas. For example, it is possible to use krypton (Kr) gas, xenon (Xe) gas, or oxygen (O₂) gas.

As the substrate holder 11 pivots again to a transport position, the lift pins lift the substrate and transport it to the transport robot.

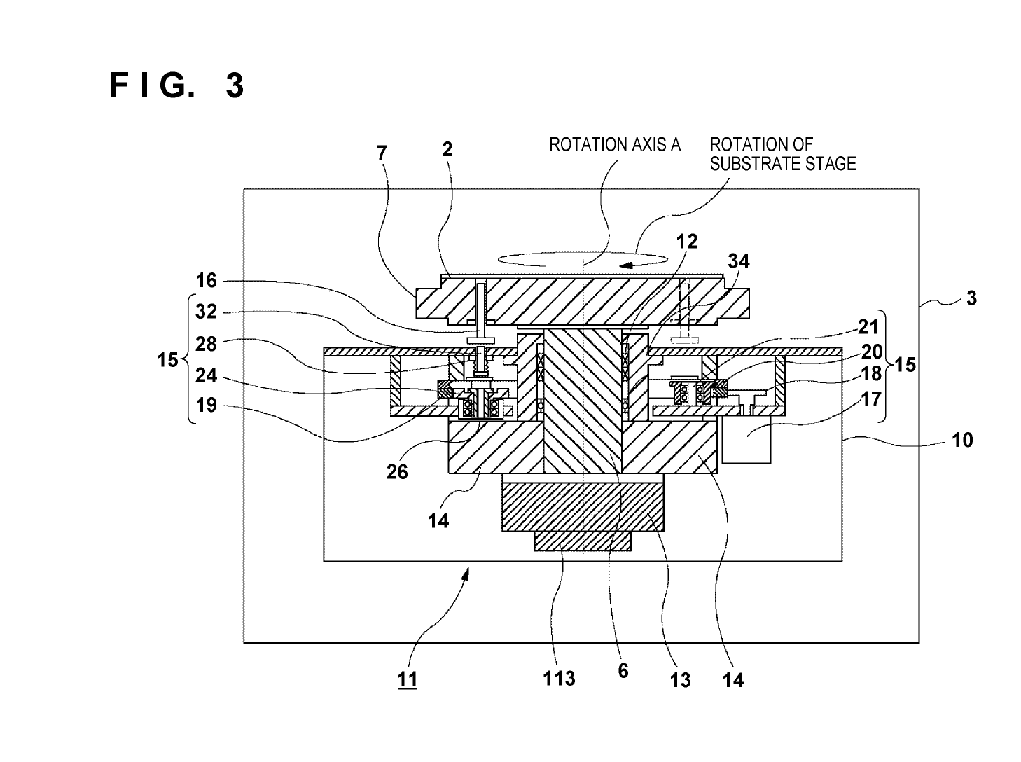

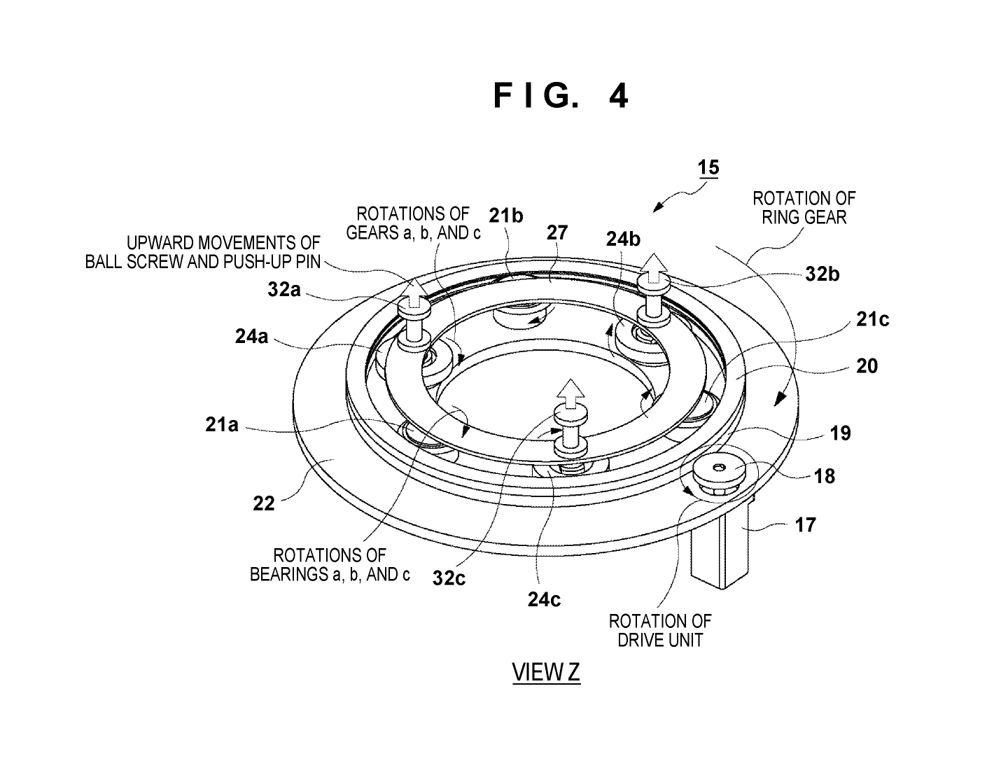

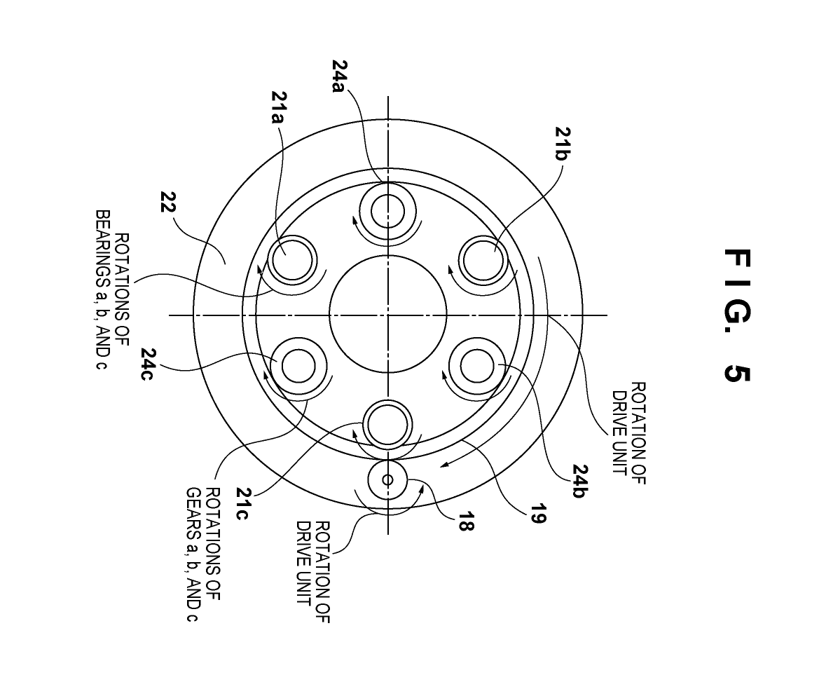

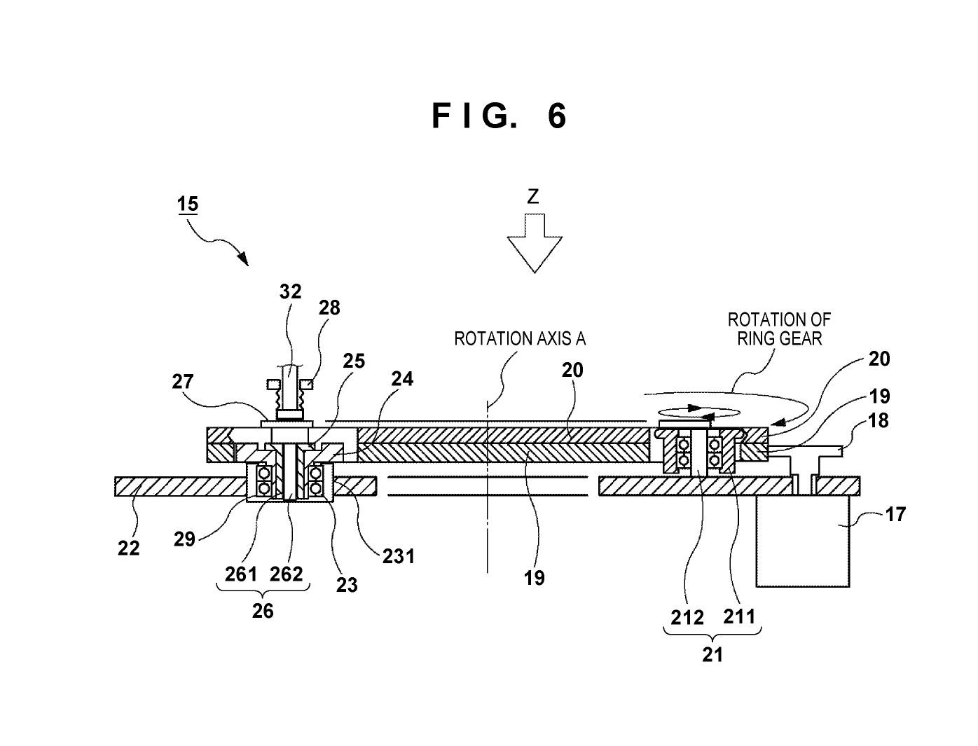

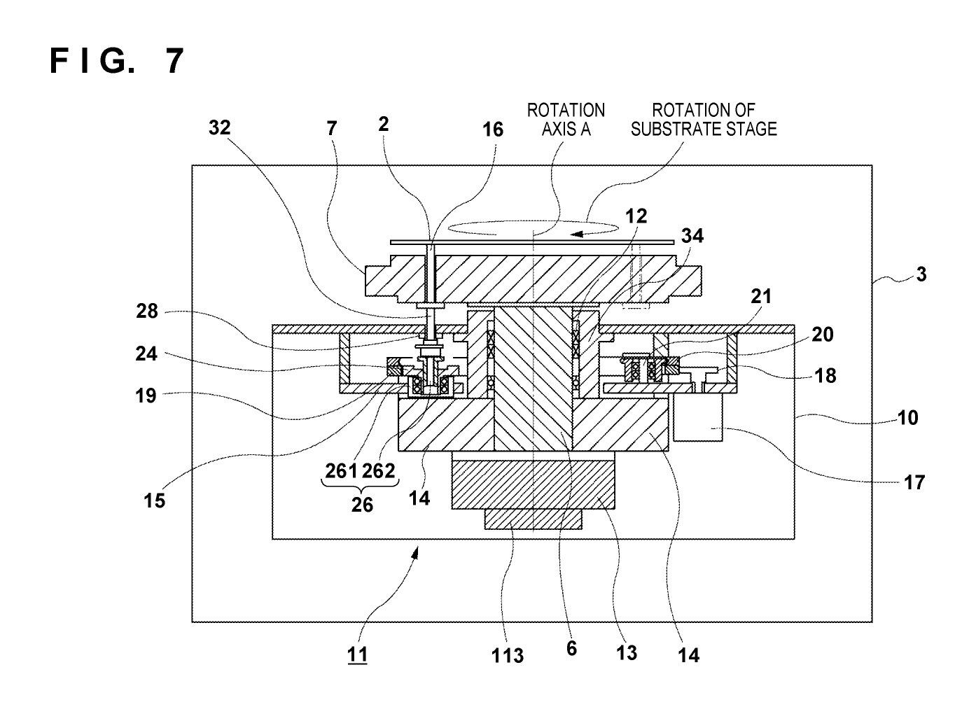

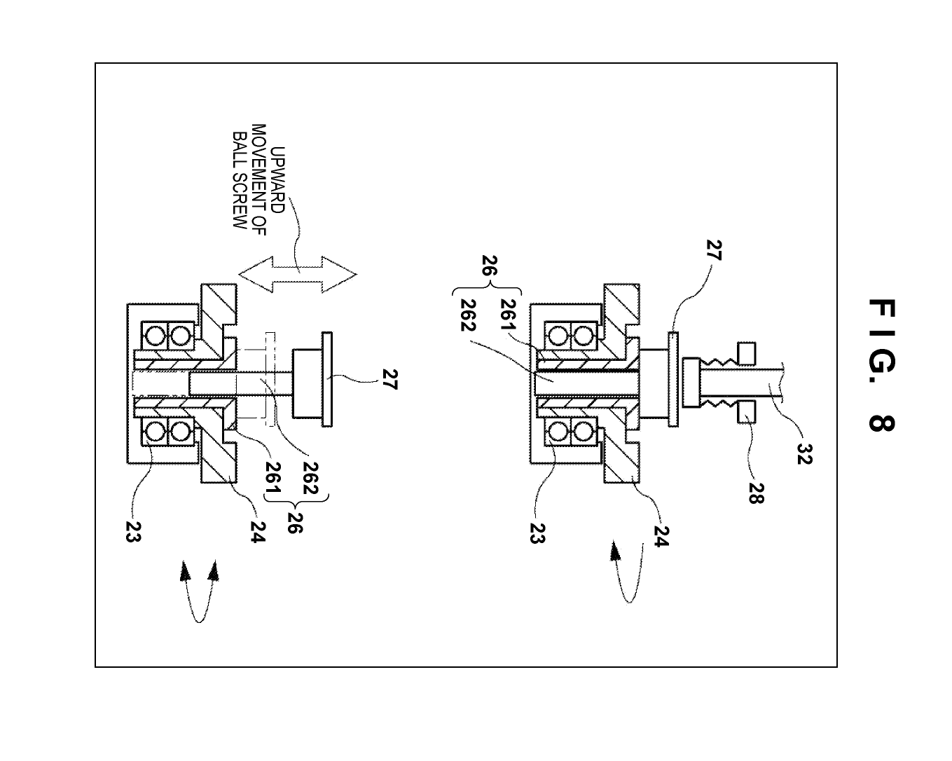

The arrangement of a substrate support apparatus (substrate holder) as a characteristic portion of the present invention will be described next with reference to FIGS. 3 to 8. FIG. 3 is a side sectional view for explaining the arrangement of the substrate holder 11 in an x-x section of FIG. 1, showing a state before an elevation unit 15 operates, that is, a state in which a substrate is mounted on the substrate stage 7. FIG. 4 is a detailed perspective view of the elevation unit 15 without the lift pins 16. FIG. 5 is a schematic plan view of a first rotating member. FIG. 6 is a side sectional view of the elevation unit 15. FIG. 7 is a side sectional view showing a state after the operation of the elevation unit 15, that is, a state in which the substrate is lifted. FIG. 8 is a schematic sectional view for explaining the operation of a mobile body (ball screw) 26.

A strut 6 which supports the substrate stage 7 and a first rotation drive portion 14 for rotating a substrate through the strut 6 are provided below the substrate stage 7 shown in FIG. 3. In this embodiment, the first rotation drive portion 14 is formed from a motor which can rotate about a rotation axis coaxial with the rotation axis A. Since the first rotation drive portion 14 is provided below the substrate stage 7, a second rotation drive portion 17 for driving the elevation unit 15 for moving the lift pins 16 up and down is disposed at a position offset from the center (rotation axis A) of the substrate stage 7. In this embodiment, the second rotation drive portion 17 is formed from a motor which can rotate about a rotation axis offset from the rotation axis A.

Since the second rotation drive portion 17 is disposed at a position offset from the rotation axis A, the vertical movement amounts of the plurality of lift pins 16 can vary due to the influences of the deformation, inclination, and the like of the elevation unit 15 which occur depending on the distance from the second rotation drive portion 17. For example, the lift pin disposed at a position far from the second rotation drive portion 17 is more susceptible to the influence of the inclination of the elevation unit 15 than the lift pin disposed at a position near the second rotation drive portion 17.

In order to solve the problem of the variations in the vertical movement amounts of the plurality of lift pins 16, the elevation unit 15 is configured to transmit the rotation of the second rotation drive portion 17 disposed at an offset position to a first rotating member 19 disposed coaxially with the rotation axis A through an outside gear 18 (transmission member). The first rotating member 19 is an annular ring gear and has gears formed on both the outer circumference side and the inner circumference side. The gear formed on the outer circumference engages with the outside gear 18 provided on the rotating shaft of the second rotation drive portion 17, thereby transmitting the rotation of the second rotation drive portion 17 to the first rotating member (ring gear) 19 and rotating the first rotating member 19 about the rotation axis A. After the rotation is converted into the rotation about the rotation axis A, that is, the rotation of the first rotating member (ring gear) 19, the rotation of the first rotating member (ring gear) 19 is converted into linear movement to move the lift pins 16 up and down. Converting the rotation of the first rotating member (ring gear) 19 about the rotation axis A makes it possible to improve the variations of the lift pins 16 due to the influences of the inclination of the elevation unit 15. This will be described in detail below with reference to the accompanying drawings.

As shown in FIG. 3, the substrate holder 11 includes the substrate stage 7, the strut 6, the first rotation drive portion 14, a support portion 10, the elevation unit 15, and the lift pins 16. The strut 6 supports the substrate stage 7. The first rotation drive portion 14 rotates the strut 6. The elevation unit 15 is provided in the support portion 10, and can vertically move the substrate 2 mounted on the substrate stage 7 by moving the lift pins 16 up and down.

The lift pins 16 are provided in the substrate stage 7. The elevating operation of the elevation unit 15 moves the lift pins 16 up and down. When the end portions of the lift pins 16 move upward to a position higher than the substrate mounting surface of the substrate stage 7, the lower surface of the substrate 2 comes into contact with the end portions of the lift pins 16 to support the substrate 2. The lift pins 16 include at least three lift pins for supporting the substrate 2. The support portion 10 is a housing which rotatably supports the strut 6. The support portion 10 is a housing having an insertion hole into which the strut 6 can be inserted. Inserting the strut 6 into the insertion hole will rotatably support the substrate stage 7. The support portion 10 functions to separate the atmospheric side from the vacuum side, and is connected to a magnetic fluid outer circumferential member 34. The magnetic fluid outer circumferential member 34 can effectively prevent the dust produced from the first or second rotation drive member or the like when the strut 6 rotates from being discharged into the process space.

The elevation unit 15 is disposed around the strut 6. The elevation unit 15 includes the first rotating member 19, the second rotation drive portion 17, a second rotating member 24, and the mobile bodies 26. The first rotating member 19 rotates around the strut 6 as rotation is transmitted to the first rotating member 19 through the outside gear 18 provided on the rotation axis of the second rotation drive portion 17. The second rotation drive portion 17 rotates to rotate the first rotating member 19. The second rotating member 24 is disposed below the lift pins 16 and rotates upon interlocking with the rotating operation of the first rotating member 19. The second rotating member 24 is constituted by at least three second rotating members 24a, 24b, and 24c disposed below the lift pins 16. Three second rotating members 24a, 24b, and 24c are annular ring gears, and gears are formed on the outer circumference sides. At least three mobile bodies (ball screws) 26 which can convert the rotations of the nuts into linear movements are respectively provided on the inner circumference sides of the second rotating members (inside gears) 24a, 24b, and 24c (FIG. 4). The gear formed on the inner circumference side of the first rotating member (ring gear) 19 meshes with the gears formed on the outer circumference sides of the second rotating members (inside gears) 24a, 24b, and 24c. As the first rotating member (ring gear) 19 rotates, the second rotating members (inside gears) 24a, 24b, and 24c rotate. The rotations of the second rotating members (inside gears) 24a, 24b, and 24c are transmitted to nuts 261 of the mobile bodies 26, and the nuts 261 rotate around ball screw shafts 262. As a consequence, the ball screw shafts 262 linearly move. The linear movement (movement amount) of the ball screw shaft 262 is determined by the pitch of the screw of the ball screw shaft 262 and the rotational speed of the nut 261. The rotational speeds of the nuts 261 of the mobile bodies (ball screws) 26 which rotate through the second rotating members (inside gears) 24a, 24b, and 24c upon rotation of the first rotating member (ring gear) 19 are the same. When using the ball screw shafts 262 having the same pitch, the movement amounts of the ball screw shafts 262 of the mobile bodies (ball screws) 26 are the same. Switching the rotating direction of the nut 261 can control the direction of vertical movement of the ball screw shaft 262. For example, a controller (not shown) can control the direction of the vertical movement of each ball screw shaft 262 by controlling the rotating direction of the second rotation drive portion 17.

The linear movements of the ball screw shafts 262 of the mobile bodies (ball screws) 26 are transmitted to the three lift pins 16 through push-up pins 32a, 32b, and 32c (FIG. 4). The three lift pins 16 move up and down owing to the linear movements transmitted from the push-up pins 32a, 32b, and 32c. The first rotation drive portion 14 is formed from a servo motor, stepping motor, or the like. The controller (not shown) can control the rotational speed of the serve motor, stepping motor, or the like. When unloading the substrate 2 from the substrate stage 7, the controller (not shown) can perform control to position the rotational position of the substrate stage 7 so as to locate push-up pins 32 immediately below the lift pins 16. After the positioning, the controller controls the rotation of the second rotation drive portion 17 to rotate/drive the outside gear 18, the first rotating member 19, the second rotating members 24, and the nuts 261. Converting such rotations into the linear movements of the ball screw shafts 262 and push-up pins 32 will move the lift pins 16 up and down.

As shown in FIGS. 6 and 8, the mobile body (ball screw) 26 includes the nut 261 and the ball screw shaft 262. The outer circumference side of the nut 261 is fixed to the inner circumference of the second rotating member 24. As the second rotating member 24 rotates, the nut 261 rotates.

As shown in FIG. 4, the second rotation drive portion 17 is disposed on the lower surface side of a base plate 22. The outside gear 18 which rotates in synchronism with the rotation of the second rotation drive portion 17 is disposed on the upper surface side of the base plate 22. As shown in FIG. 5, the outside gear 18 engages with the gear on the outer circumference side of the first rotating member (ring gear) 19. In addition, the second rotating members (inside gears) 24 are rotatably held by bearings 23 (FIG. 6) disposed coaxially with the center axes of the second rotating members 24 while meshing with the gear on the inner circumference side of the first rotating member (ring gear) 19. A guide ring 20 fixed on the upper surface side of the first rotating member (ring gear) 19 is held by three bearings 21a, 21b, and 21c so as to be rotatable around the rotation axis (rotation axis A) of the substrate stage 7.

As shown in FIG. 4, the second rotating members (inside gears) 24 (24a, 24b, and 24c) are arranged at equal intervals on the upper surface side of the base plate 22 concentrically around the rotation axis A. The bearing 21b is disposed between the second rotating members 24a and 24b. The bearing 21c is disposed between the second rotating members 24b and 24c. The bearing 21a is disposed between the second rotating members 24a and 24c.

As shown in FIG. 6, a convex portion whose end portion has a curvature is formed on the outer circumferential surface of the upper portion of an outer ring 211 of each of the bearings 21 (21a, 21b, and 21c). This R-shaped convex portion is in contact with the V-shaped groove formed in the inner circumferential surface of the guide ring 20 to support the rotation of the guide ring 20. The first rotating member (ring gear) 19 coaxial with the rotation axis of the guide ring 20 is fixed on the lower surface side of the guide ring 20. The shape (inner shape, outer shape, and thickness) of the first rotating member (ring gear) 19 is the same as that of the guide ring 20.

The elevation unit 15 lift the lift pins 16 on the vacuum side by lifting the push-up pins 32 integrated with bellows 28 from the atmospheric side. The end portions of the lifted lift pins 16 come into contact with the lower surface of the substrate 2, and the substrate 2 is lifted as the lift pins 16 move upward (FIG. 7). As the lift pins 16 move downward, the substrate 2 also moves downward. When the end portions of the lift pins 16 move downward below the substrate mounting surface of the substrate stage 7, the substrate 2 supported by the lift pins 16 is mounted from the lift pins 16 onto the substrate mounting surface (FIG. 3).

As shown in FIG. 6, the mobile body (ball screw) 26 and the bearing 23 are disposed coaxially with the center axis of the second rotating member (inside gear) 24. The inside gear 24, the nut 261 of the mobile body (ball screw) 26, and the inner ring of the bearing 23 are fixed to each other and rotate together as the first rotating member (ring gear) 19 rotates. The outer ring of the bearing 23 is fixed to the base plate 22 through a bearing outer circumferential member 29. The second rotating member (inside gear) 24 is rotatably held in this place. Note that as shown in FIG. 4, coupling the upper end portions of the ball screw shafts 262 disposed at three portions to a ring plate 27 will stop the rotation of the ball screw shafts 262 of the mobile bodies (ball screws) 26 shown in FIG. 5. The nut 261 rotates independently of the ball screw shaft 262. As the nut 261 rotates, the ball screw shaft 262 moves up and down.

As the first rotating member (ring gear) 19 rotates, the second rotating members (inside gears) 24 meshing with the gear on the inner circumference side of the first rotating member 19 rotate in synchronism with the first rotating member (ring gear) 19. Although this embodiment uses the second rotating members (inside gears) 24 at the three portions, the spirit and scope of the present invention are not limited to this. Second rotating members may be attached to three or more portions.

The ascending ring plate 27 pushes up the push-up pins 32 integrally manufactured with the bellows 28 to push up the lift pins 16 on the vacuum side, thereby lifting the substrate 2. With the above arrangement, even when actuating the second rotation drive portion 17 disposed at a position offset from the rotation axis A of the substrate stage, it is possible to vertically move the substrate 2 without any variations in the vertical movements of the lift pins 16.

It is preferable to dispose the push-up pin 32 and the lift pin 16 immediately above the ball screw shaft 262. This disposition can prevent a moment load from acting on the ball screw shaft 262. This makes it possible to prevent a marked decrease in the service life of the mobile body (ball screw) 26 without using any guide member as an auxiliary member for keeping linearity, such as a linear bush. This is effective in improving the reliability of this apparatus and reducing its cost.

The substrate stage 7 includes an electrostatic attraction electrode (not shown) a power instruction unit 13 for applying a voltage to the electrostatic attraction electrode, and a cooling water introduction unit 113 for introducing cooling water into pipes formed in the substrate stage 7 to cool the substrate 2. A magnetic fluid 12 is provided between the rotating strut 6 and the magnetic fluid outer circumferential member 34 provided on the fixed support portion 10 to separate the vacuum space from the atmospheric space.

The following is the operation of lifting the substrate 2 mounted on the substrate stage 7 by using the substrate holder 11 in this embodiment. As shown in FIG. 3, as the second rotation drive portion 17 drives, both the outside gear 18 and the second rotation drive portion 17 rotate coaxially with the rotation axis. As the outside gear 18 rotates, the first rotating member (ring gear) 19 meshing with the outside gear 18 on the outer ring side also begins to rotate about the rotation axis A (the rotation axis of the strut 6).

As shown in FIG. 5, the second rotating members (inside gears) 24 (24a, 24b, and 24c) at the three portions which mesh with the gear on the inner circumference side of the first rotating member (ring gear) 19 rotate simultaneously with the rotation of the first rotating member (ring gear) 19.

Accompanying the rotation of the second rotating members (inside gears) 24 (24a, 24b, and 24c), the nuts 261 of the mobile bodies (ball screws) 26 disposed coaxially on the second rotating members (inside gears) 24 (24a, 24b, and 24c) rotate, as shown in FIG. 6. The rotating movements of the nuts 261 are converted into the linear movements of the ball screw shafts 262. As a consequence, the ball screw shafts 262 move upward. Accompanying this upward movement, the ring plate 27 coupled to the ball screw shafts 262 also moves upward. The ring plate 27 pushes up the bottom surfaces of at least the three bellows 28 disposed immediately above the at least the three mobile bodies (ball screws) 26. As a consequence, the push-up pins 32a, 32b, and 32c integrally manufactured with the bellows 28 are also simultaneously pushed up. In this manner, the push-up pins 32 can push up at least the three lift pins 16 disposed immediately above the bellows 28. Lastly, as shown in FIG. 6, at least the three lift pins 16 push up the substrate 2.

### Second Embodiment

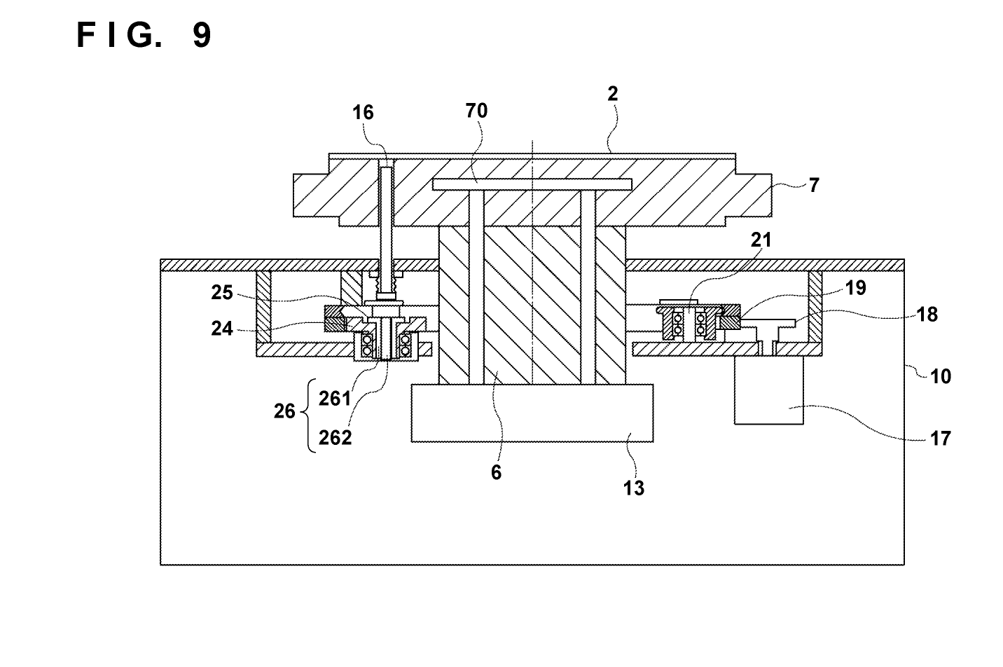

FIG. 9 is a schematic sectional view of a substrate processing apparatus according to the second embodiment which can be applied to the present invention. The substrate processing apparatus of this embodiment basically has the same arrangement as that of the substrate holder 11 shown in FIG. 3. The same reference numerals denote the same constituent members, and a detailed description of them will be omitted. The substrate processing apparatus of this embodiment differs from the substrate support apparatus (substrate holder) of the first embodiment in that since a strut 6 and a substrate stage 7 do not rotate, the first rotation drive portion 14 is not provided. Instead of this component, a power instruction unit 13 for introducing power to an electrostatic attraction element 70 provided in the substrate stage 7 is disposed below the strut 6. A second rotation drive portion 17 cannot be disposed at the central portion of the substrate stage 7, and hence is disposed at a position offset from the central portion (rotation axis A) of the substrate stage 7 as in the first embodiment. In the substrate support apparatus (substrate holder) of this embodiment, since the substrate stage 7 does not rotate, there is no need to provide push-up pins 32 and lift pins 16 as discrete components. That is, this apparatus is configured to allow the lift pins 16 to directly move the substrate 2 up and down.

Note that the outside gear 18, the first rotating members (ring gears) 19, and the second rotating member (inside gear) 24 in the first and second embodiments can be implemented by being replaced with pulleys and timing belts.

Assume that the outside gear 18 is replaced with an outside pulley, and the first rotating member 19 is replaced with a first rotating pulley. In this case, coupling the outside pulley to the first rotating pulley through a first timing belt (first belt) makes it possible to transmit the rotation of the outside pulley to the first rotating pulley through the belt.

If the second rotating member 24 is replaced with a second rotating pulley, it is possible to transmit the rotation of the first rotating pulley to the second rotating pulley through a second timing belt (second belt) which couples the first rotating pulley to the second rotating pulley.

### Third Embodiment

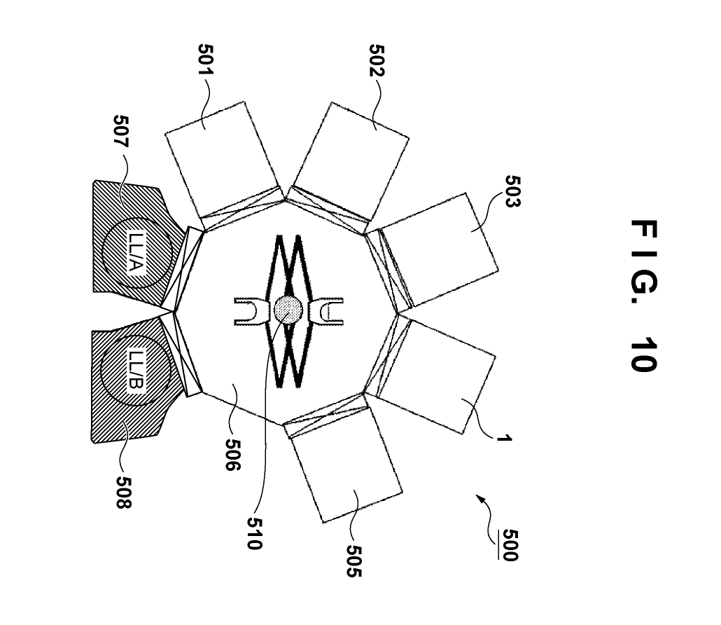

FIG. 10 is a plan view for explaining an electronic device manufacturing apparatus according to the third embodiment. An electronic device manufacturing apparatus 500 shown in FIG. 10 is a so-called clustered processing system. The electronic device manufacturing apparatus 500 has, in its central portion, a vacuum transport chamber 506 including two transport robots 510. Four PVD (sputtering) chambers 501, 502, 503, and 504, two load lock chambers 507 and 508, and an ion beam etching apparatus 505 are coupled to each other through gate valves around the vacuum transport chamber 506. An exhaust unit is connected to each chamber, and can reduce the pressure in the vessel. An ion beam etching apparatus (IBE apparatus) 1 shown in FIG. 10 includes a substrate holder 11 (described above). Note that in the electronic device manufacturing apparatus of this embodiment, the SEMI/MESC standards impose restrictions on the reach of the stretchable arm of the transport robot 510. The distance from the connecting surface with the vacuum transport chamber 506 of this substrate processing apparatus to the center of the substrate holder 11 (FIG. 1) of the ion beam etching apparatus 505 is defined.

Note that the substrate processing apparatus of the present invention can be configured by combining any features described in the respective embodiments.

The present invention is not limited to the above-described embodiments, and various changes and modifications can be made within the spirit and scope of the present invention. Therefore, to apprise the public of the scope of the present invention, the following claims are made.

This application claims the benefit of Japanese Patent Application No. 2010-227465, filed Oct. 7, 2010, which is hereby incorporated by reference herein in its entirety.

1. (canceled)

2. A substrate processing apparatus including a substrate stage, a strut which supports the substrate stage, and at least three lift pins which are provided in the substrate stage and configured to vertically move in a vertical direction relative to a surface of the substrate stage on which a substrate is mounted, comprising:
an elevation unit configured to vertically moving the lift pins,
said elevation unit comprising
a first rotating member which is disposed around the support and rotates about the support coaxially with a rotation axis of the support,
a rotation drive portion which rotates about a rotation axis at a position offset from the rotation axis and rotates said first rotating member by transmitting the rotation to said first rotating member through a transmission member,
at least three second rotating members which rotate while engaging with rotation of said first rotating member and are disposed below the lift pins, and
mobile bodies which linearly move upon rotation of said second rotating members,
wherein the lift pins vertically move upon linear movements of said mobile bodies.

3. The substrate processing apparatus according to claim 2, wherein the first rotating member comprises a member having a ring shape, and gears are formed on an outer circumference side and an inner circumference side of the ring shape.

4. The substrate processing apparatus according to claim 3, wherein said transmission member comprises a gear which engages with the gear formed on the outer circumference side of said first rotating member.

5. The substrate processing apparatus according to claim 3, wherein a gear which engages with the gear formed on the inner circumference side of said first rotating member is formed on an outer circumferential portion of said second rotating member.

6. The substrate processing apparatus according to claim 2, further comprising a second rotation drive portion which rotates the strut which supports the substrate stage.
